(19) United States
(12) Patent Application Publication
(10) Pub. No.: US 2015/0372139 A1
(43) Pub. Date: Dec. 24, 2015

(54) CONSTRAINING EPITAXIAL GROWTH ON FINS OF A FINFET DEVICE

(71) Applicant: GLOBALFOUNDERS Inc., Grand Cayman (KY)

(72) Inventors: Andy C. Wei, Queensbury, NY (US); Konstantin Korablev, Saratoga Springs, NY (US)

(21) Appl. No.: 14/308,003

(22) Filed: Jun. 18, 2014

(51) Int. Cl. H01L 29/78; H01L 21/8238; H01L 27/092; H01L 29/165; H01L 29/66

(52) U.S. Cl. CPC H01L 29/7848; H01L 29/785; H01L 29/165; H01L 29/66795; H01L 29/66545; H01L 27/0924; H01L 21/823807

(57) ABSTRACT

A method includes forming at least one fin in a semiconductor substrate, forming a fin spacer on at least a first portion of the fin, the fin spacer having an upper surface, recessing the at least one fin to thereby define a recessed fin with a recessed upper surface that it is at a level below the upper surface of the fin spacer, and forming a first epitaxial material on the recessed fin, wherein a lateral extension of the epitaxial material is constrained by the fin spacer.

### BACKGROUND OF THE INVENTION

1. Field of the Invention

The present disclosure generally relates to the fabrication of semiconductor devices, and, more particularly, to a method for constraining epitaxial growth on fins of a finFET device.

2. Description of the Related Art

In modern integrated circuits, such as microprocessors, storage devices and the like, a very large number of circuit elements, especially transistors, are provided and operated on a restricted chip area. In integrated circuits fabricated using metal-oxide-semiconductor (MOS) technology, field effect transistors (FETs) (both NMOS and PMOS transistors) are provided that are typically operated in a switching mode. That is, these transistor devices exhibit a highly conductive state (on-state) and a high impedance state (off-state). FETs may take a variety of forms and configurations. For example, among other configurations, FETs may be either so-called planar FET devices or three-dimensional (3D) devices, such as FinFET devices.

A field effect transistor (FET), irrespective of whether an NMOS transistor or a PMOS transistor is considered, and irrespective of whether it is a planar or 3D FinFET device, typically comprises doped source/drain regions that are formed in a semiconductor substrate that are separated by a channel region. A gate insulation layer is positioned above the channel region and a conductive gate electrode is positioned above the gate insulation layer. The gate insulation layer and the gate electrode may sometimes be referred to as the gate structure for the device. By applying an appropriate voltage to the gate electrode, the channel region becomes conductive and current is allowed to flow from the source region to the drain region. In a planar FET device, the gate structure is formed above a substantially planar upper surface of the substrate. In some cases, one or more epitaxial growth processes are performed to form epitaxial (epi) semiconductor material in recesses formed in the source/drain regions of the planar FET device. In some cases, the epi material may be formed in the source/drain regions without forming any recesses in the substrate for a planar FET device, or the recesses may be overfilled, thus forming raised source/drain regions. The gate structures for such planar FET devices may be manufactured using so-called “gate-first” or “replacement gate” (gate-last) manufacturing techniques.

To improve the operating speed of FETs, and to increase the density of FETs on an integrated circuit device, device designers have greatly reduced the physical size of FETs over the years. More specifically, the channel length of FETs has been significantly decreased, which has resulted in improving the switching speed of FETs. However, decreasing the channel length of a FET also decreases the distance between the source region and the drain region. In some cases, this decrease in the separation between the source and the drain makes it difficult to efficiently inhibit the electrical potential of the source region and the channel from being adversely affected by the electrical potential of the drain. This is sometimes referred to as a so-called short channel effect, wherein the characteristic of the FET as an active switch is degraded.

In contrast to a FET, which has a planar structure, a so-called FinFET device has a three-dimensional (3D) structure. FIG. 1A is a perspective view of an illustrative prior art FinFET semiconductor device 100 that is formed above a semiconductor substrate 105. In this example, the FinFET device 100 includes three illustrative fins 110, a gate structure 115, sidewall spacers 120 and a gate cap 125. The gate structure 115 is typically comprised of a layer of insulating material (not separately shown), e.g., a layer of high-k insulating material or silicon dioxide, and one or more conductive material layers (e.g., metal and/or polysilicon) that serve as the gate electrode for the device 100. The fins 110 have a three-dimensional configuration. The portions of the fins 110 covered by the gate structure 115 is the channel region of the FinFET device 100. An isolation structure 130 is formed between the fins 110. In a conventional process flow, the portions of the fins 110 that are positioned outside of the spacers 120, i.e., in the source/drain regions of the device 100, may be increased in size or even merged together by performing one or more epitaxial growth processes. The process of increasing the size of the fins 110 in the source/drain regions of the device 100 is performed to reduce the resistance of source/drain regions and/or make it easier to establish electrical contact to the source/drain regions.

FIG. 1B illustrates a cross-sectional view depicting the formation of epi semiconductor material on various fins across the substrate 105, including fins for the finFET device 100. The epi material is formed in the source/drain regions of the finFET devices. The fins 110 shown in FIG. 1A are densely-spaced fins. Additional isolated fins 135 are illustrated representing a different region of the substrate 105. For example, the densely-spaced fins 110 may be part of a logic device or SRAM NFET, while the isolated fins 135 may be part of an SRAM PFET. During an epi material growth process, the growth starts in the direction of a (111) crystallographic plane of the substrate 105. In the case of the densely spaced fins 110, the epi regions can grow between the fins 110 and merge to form a substantially horizontal surface. Further growth from the horizontal surface occurs in a direction corresponding to a (100) plane of the substrate. Growth occurs much faster in a (100) plane as compared to a (111) plane, thus resulting in a merged epi structure 140 above the densely-spaced fins 110 and discrete epi structures 145 above the isolated fins 135.

A device with the merged epi structure 140 can have different device characteristics as compared to a device with the discrete epi structure 145. For example, the resistance of the device may be higher for the device with the merged epi structure 140. Conductive contact structures will eventually be formed to the source/drain regions of the device. Due to the higher topology of the merged epi structure 140, the contact etches terminate differently, and the contact structures have different sizes. This size difference results in a difference in resistance. In addition, the fins 110 may be associated with separate devices (e.g., an N-channel device and a P-channel device), and the merged epi structure 140 may cause a short circuit between the fins 110 of the separate devices, which may destroy their functionality.

The present disclosure is directed to various methods and resulting devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming semiconductor devices. A method includes forming at least one fin in a semiconductor substrate, forming a fin spacer on at least a first portion of the fin, the fin spacer having an upper surface, recessing the at least one fin to thereby define a recessed fin with a recessed upper surface that it is at a level below the upper surface of the fin spacer, and forming a first epitaxial material on the recessed fin, wherein a lateral extension of the epitaxial material is constrained by the fin spacer.

One illustrative fin field effect transistor includes, among other things, at least one fin, a fin spacer formed on at least a first portion of the at least one fin, and first epitaxial material disposed on a tip portion of the at least one fin and at least partially laterally constrained by the fin spacer.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1B schematically depict an illustrative prior art finFET device; and

FIGS. 2A-2K depict various methods disclosed herein of forming a finFET device.

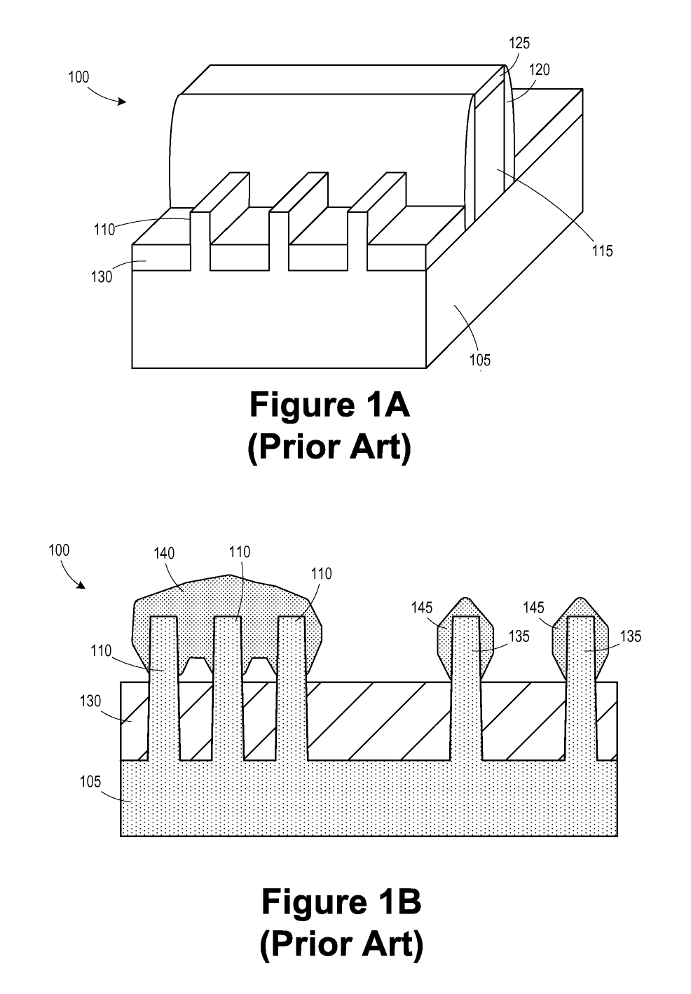

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally relates to various methods of forming a finFET device with raised epitaxial source/drain regions without causing merging of the epi material above densely-spaced fins and the resulting semiconductor devices. As will be readily apparent to those skilled in the art upon a complete reading of the present application, the present method is applicable to a variety of devices, including, but not limited to, logic devices, memory devices, etc. With reference to the attached figures, various illustrative embodiments of the methods and devices disclosed herein will now be described in more detail.

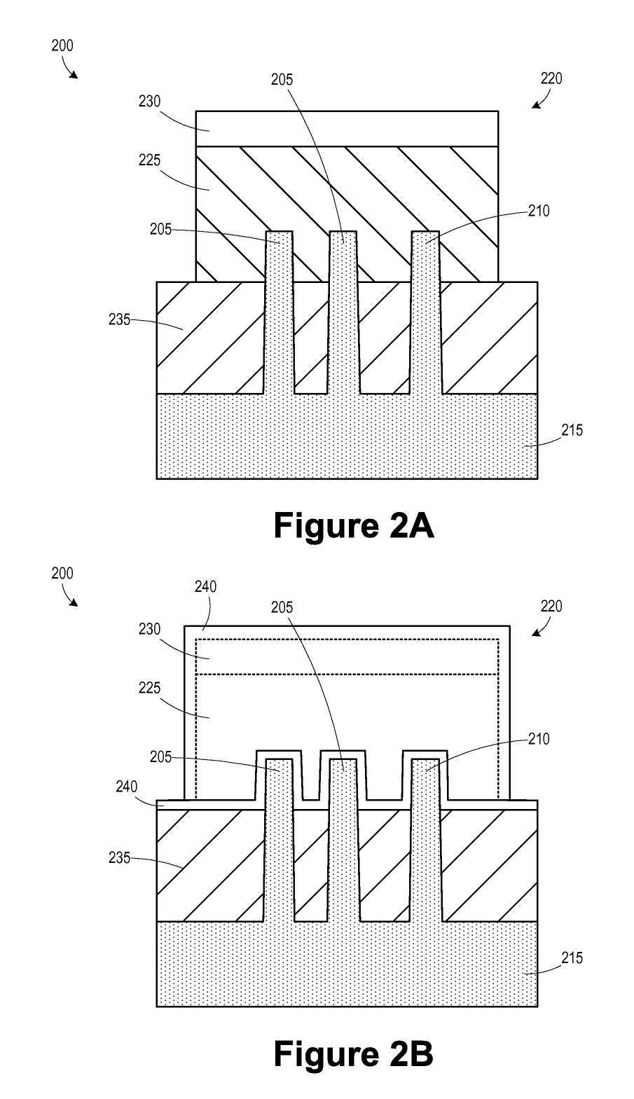

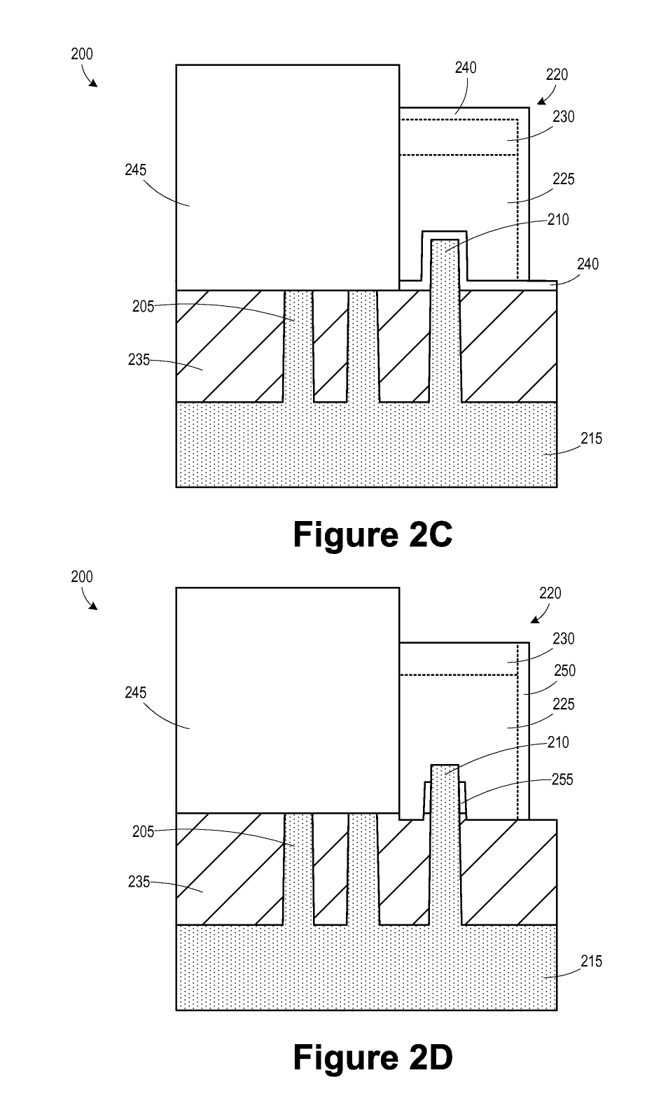

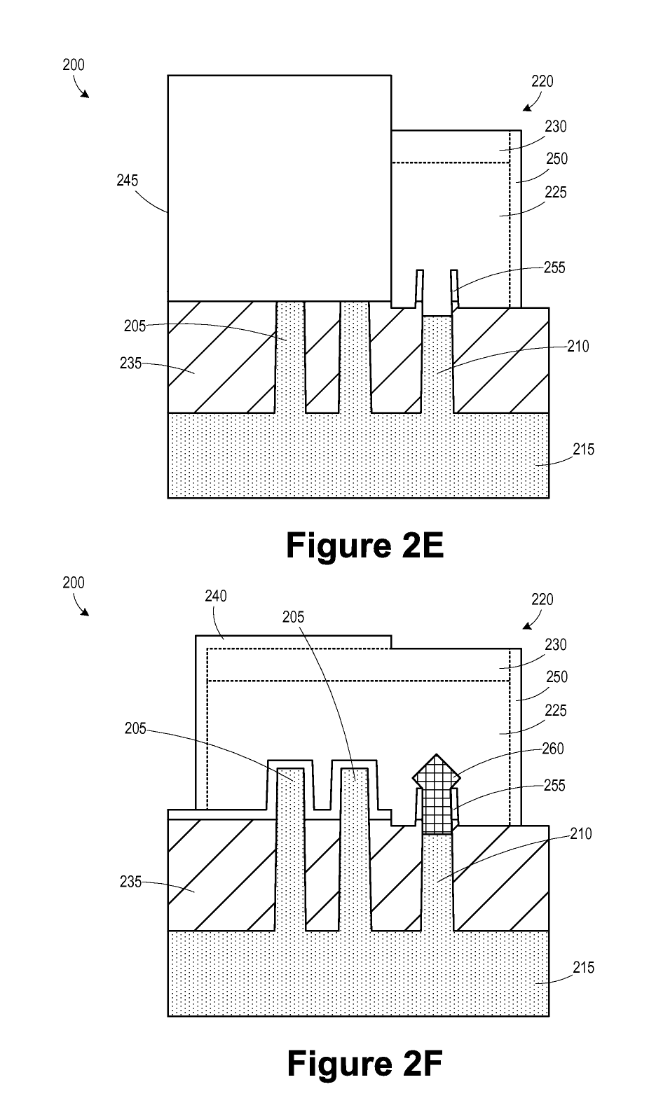

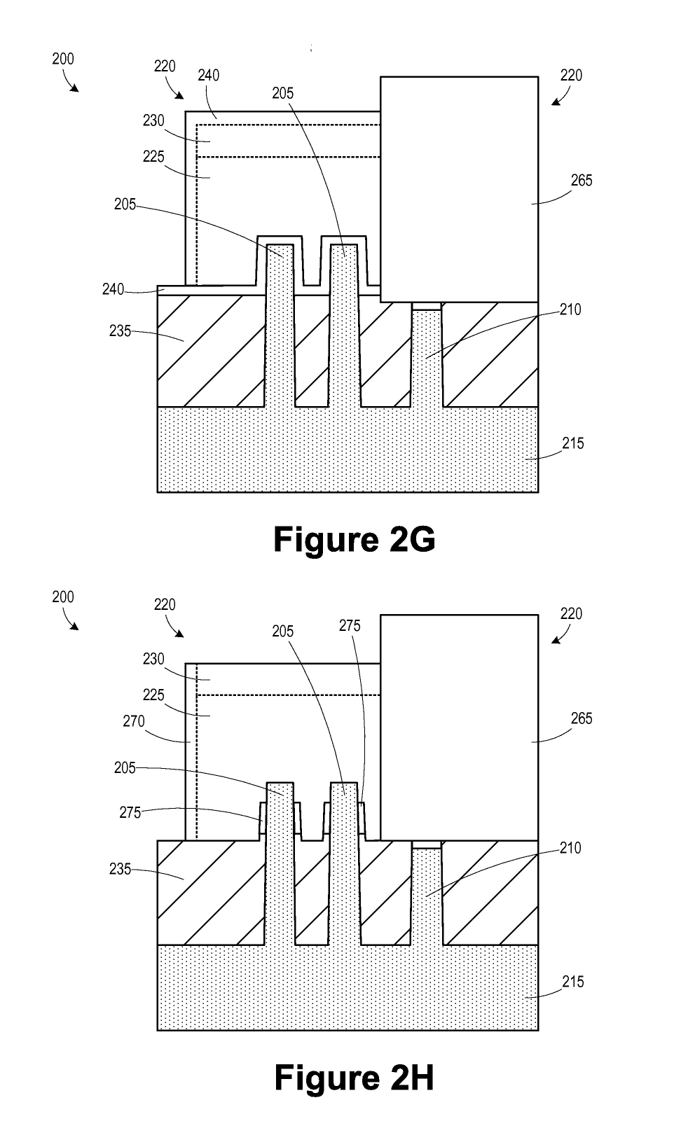

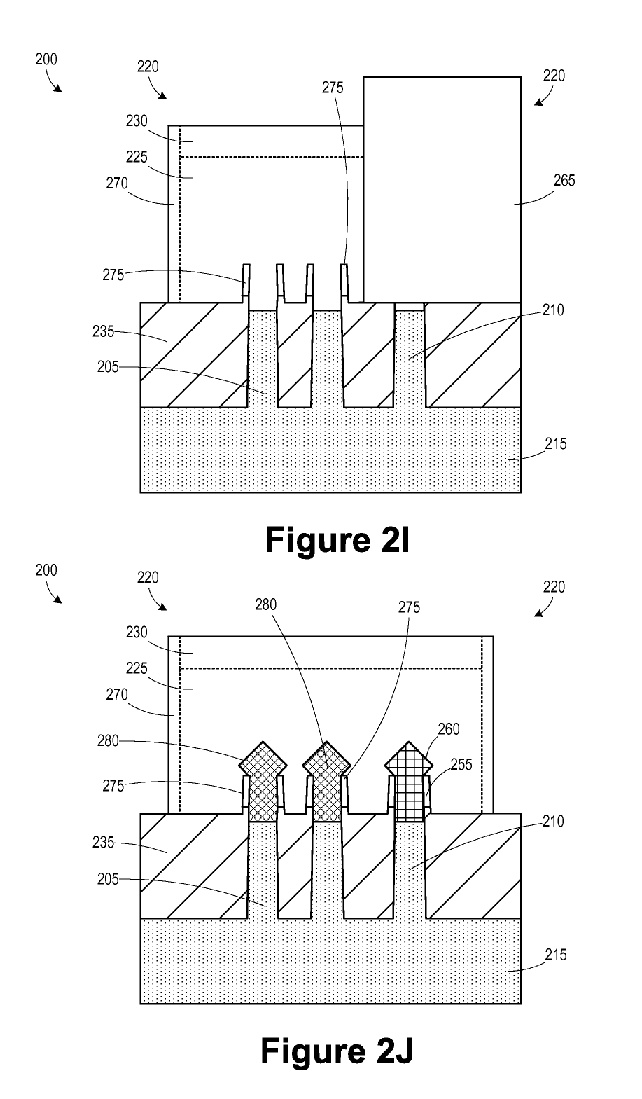

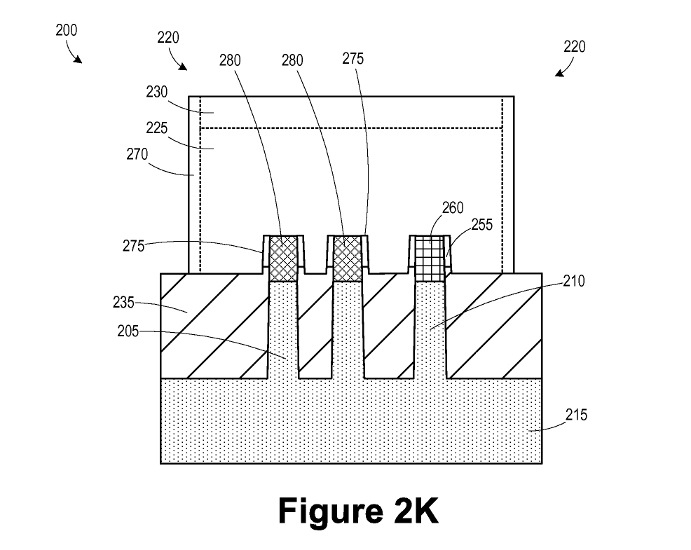

FIGS. 2A-2K illustrate various novel methods disclosed herein for forming a finFET device 200. FIGS. 2A-2K show a cross-sectional view of fins 205 of an N-type device and a fin 210 of a P-type device defined in a substrate 215 and sharing a common placeholder gate electrode structure 220. The cross-section is taken across the fins 205, 210 in front of the placeholder gate electrode structure 220. The number of fins 205, 210, and the spacing between fins may vary depending on the particular characteristics of the device(s) being formed. Various doped regions, e.g., halo implant regions, well regions and the like, may be formed, but are not depicted in the attached drawings. The substrate 215 may have a variety of configurations, such as the depicted bulk silicon configuration. The substrate 215 may also have a silicon-on-insulator (SOI) configuration that includes a bulk silicon layer, a buried insulation layer and an active layer, wherein semiconductor devices are formed in and above the active layer. The substrate 215 may be formed of silicon or silicon germanium or it may be made of materials other than silicon, such as germanium. Thus, the terms “substrate” or “semiconductor substrate” should be understood to cover all semiconducting materials and all forms of such materials. The substrate 215 may have different layers. For example, the fins 205, 210 may be formed in a process layer formed above the base layer of the substrate 215.

In one illustrative embodiment, a replacement gate technique is used to form the finFET device 200, and the placeholder gate electrode structure 220 is illustrated prior to the formation of the replacement gate structure. The placeholder gate electrode structure 220 includes a sacrificial placeholder material 225, such as polysilicon, and a gate insulation layer (not separately shown), such as silicon dioxide. Also depicted is an illustrative gate cap layer 230 (e.g., silicon nitride). An insulating layer 235 (e.g., silicon dioxide) is formed between the fins 210, 215 to serve as an isolation structure. However, the application of the present subject matter is not limited to a replacement gate or “gate-last” technique, but rather, a gate-first technique may also be used, and the placeholder gate electrode structure 220 may be replaced with a functional gate electrode structure including a gate insulation layer and a conductive gate electrode.

FIG. 2B illustrates the finFET device 200 after forming a spacer material 240 (e.g., silicon nitride) above the placeholder gate electrode structure 220 and the fins 205, 210. The placeholder material 225 and the gate cap layer 230 are shown in phantom. The relative thicknesses of the gate cap layer 230 and the spacer layer 240 may vary depending on the particular embodiment.

FIG. 2C illustrates the finFET device 200 after forming a mask 245 (e.g., photoresist) above the fins 205, i.e., the N-type device is masked.

FIG. 2D illustrates the finFET device 200 after performing an anisotropic spacer etch process to form a sidewall spacer 250 on the placeholder material 225. The spacer etch process also recesses the insulating layer 235 and reduces the thickness of the cap layer 230. The spacer etch process is terminated prior to completely removing the spacer material 240 on the sidewalls of the fin 210, thereby leaving fin spacers 255 that partially cover the sidewalls of the fin 210.

FIG. 2E illustrates the finFET device 200 after performing a selective etch process to recess the fin 210. FIG. 2F illustrates the finFET device 200 after removing the mask 245 and performing an epitaxial growth process to form epi material 260 on the exposed tip portions of the fin 210. The fin spacers 255 constrain the lateral growth of the epi material 260, limiting its lateral extension in the direction toward the other fins 205. In some embodiments, a dopant (e.g., a P-type dopant) may be introduced into the epi material 260 while it is being formed. In some embodiments, a non-doping ion (e.g., Ge, Sn) having a covalent radius greater than silicon may also be introduced into the epi material 260 to induce compressive strain on a channel region of the finFET device 200.

FIG. 2G illustrates the finFET device 200 after forming a mask 265 (e.g., photoresist) above the fin 210, i.e., the P-type device is masked. FIG. 2H illustrates the finFET device 200 after performing an anisotropic spacer etch process to form a sidewall spacer 270 on the placeholder material 225. The spacer etch process recesses the insulating layer 235 and also reduces the thickness of the cap layer 230. The spacer etch process is terminated prior to completely removing the spacer material 240 on the sidewalls of the fin 210, thereby leaving fin spacers 275 that partially cover the sidewalls of the fins 205.

FIG. 2I illustrates the finFET device 200 after performing a selective etch process to recess the fins 205. FIG. 2J illustrates the finFET device 200 after removing the mask 265 and performing an epitaxial growth process to form epi material 280 on the exposed tip portions of the fins 205. The fin spacers 275 constrain the lateral growth of the epi material 280, limiting its lateral extension in the direction of each other and in the direction of the other fin 210 of the P-type device. In some embodiments, a dopant (e.g., an N-type dopant) may be introduced into the epi material 280 while it is being formed. In some embodiments, the epi material 280 may be non-stress-inducing. In other embodiments, a non-doping ion having a covalent radius less than silicon (e.g., carbon) may also be introduced into the epi material 280 to induce tensile strain on the channel region of the finFET device 200 below the placeholder gate electrode structure 220.

FIG. 2K illustrates an alternative embodiment of the finFET device 200, where the epi material 260, 280 is constrained such that the tip portions do not exhibit substantial growth in the lateral direction toward the adjacent fins 205, 210. The degree of desired lateral extension may be controlled based on the height of the fin spacers 255, 275 or the processing time for the epitaxial growth processes.

Due to the presence of the fin spacers 255, 275 during the epitaxial growth processes, the epi material 260, 280 grown on the tips of the fins 210, 205, respectively, does not merge across adjacent fins 205, 210, thereby preventing shorts between devices. Preventing merging between fins also provides a consistent fin height across regions of different fin density.

Additional processing steps (not shown) may be performed to complete fabrication of the finFET device 200, such as implantation steps to dope the source/drain regions of the finFET device 200. The placeholder material 225 may be removed and replaced with a gate dielectric layer and a metal gate electrode. Silicidation processes may be performed to form contact areas on the finFET device 200, and subsequent metallization layers and interconnect lines and vias may be formed. Other layers of material, such as a stress-inducing contact etch stop layer and the like, may be present but are not depicted in the attached drawings.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A method, comprising:
forming at least one fin in a semiconductor substrate;
forming a fin spacer on at least a first portion of said at least one fin, said fin spacer having an upper surface;
recessing said at least one fin to thereby define a recessed fin with a recessed upper surface that it is at a level below said upper surface of said fin spacer; and
forming a first epitaxial material on said recessed fin, wherein a lateral extension of said first epitaxial material is constrained by said fin spacer.

2. The method of claim 1, further comprising:
forming a gate structure around a second portion of said at least one fin;
forming a spacer material layer above said gate structure and said at least one fin;
etching said spacer material to form said fin spacer and to form a sidewall spacer on said gate structure.

3. The method of claim 1, wherein forming said at least one fin comprises forming a plurality of fins, each of said plurality of fins having fin spacers, and forming said first epitaxial material comprises forming a discrete epitaxial material structure on each of said plurality of fins.

4. The method of claim 1, wherein said first epitaxial material comprises a strain-inducing material.

5. The method of claim 4, wherein said strain-inducing material comprises silicon germanium.

6. The method of claim 1, wherein said first epitaxial material comprises silicon.

7. The method of claim 1, wherein said first epitaxial material has an upper surface at a level even with or below said upper surface of said fin spacer.

8. The method of claim 1, wherein said at least one fin comprises a first fin associated with a P-type transistor device, and the method further comprises:
forming a second fin associated with an N-type transistor device in said semiconductor substrate;
forming a second fin spacer on at least a first portion of said second fin, said second fin spacer having a second upper surface;
recessing said second fin to thereby define a recessed second fin with a second recessed upper surface that is at a level below said second upper surface of said second fin spacer; and
forming a second epitaxial material on said second recessed fin, wherein a lateral extension of said second epitaxial material is constrained by said second fin spacer.

9. The method of claim 8, wherein said first epitaxial material comprises a different material than said second epitaxial material.

10. The method of claim of claim 9, wherein said first epitaxial material is strain-inducing and said second epitaxial material is non-strain-inducing.

11. A fin field effect transistor, comprising:
at least one fin;
a fin spacer formed on at least a first portion of said at least one fin; and
first epitaxial material disposed on a tip portion of said at least one fin and at least partially laterally constrained by said fin spacer.

12. The transistor of claim 11, further comprising:
a sacrificial gate structure formed around a second portion of said at least one fin; and
a sidewall spacer formed on said sacrificial gate structure, wherein said fin spacer and said sidewall spacer comprise the same material.

13. The transistor of claim 11, further comprising:
a plurality of fins, each of said plurality of fins having a fin spacer; and
a discrete epitaxial material structure on each of said plurality of fins.

14. The transistor of claim 11, wherein said first epitaxial material comprises a strain-inducing material.

15. The transistor of claim 14, wherein said strain-inducing material comprises silicon germanium.

16. The transistor of claim 11, wherein said first epitaxial material comprises silicon.

17. The transistor of claim 11, wherein said first epitaxial material has a height less than or equal to a height of said fin spacer.

18. The transistor of claim 11, wherein said at least one fin comprises a first fin associated with a P-type transistor device, and the transistor further comprises:
a second fin associated with an N-type transistor device;
a second fin spacer on at least a first portion of said second fin; and
second epitaxial material disposed on a tip portion of said second fin and at least partially laterally constrained by said second fin spacer.

19. The transistor of claim 18, wherein said first epitaxial material comprises a different material than said second epitaxial material.

20. The transistor of claim of claim 19, wherein said first epitaxial material is strain-inducing and said second epitaxial material is non-strain-inducing.
